(19) United States
(12) Patent Application Publication
(10) Pub. No.: US 2026/0305207 A1
(43) Pub. Date: Oct. 1, 2026

(54) METHOD FOR CONTROLLED SPALLING OF HIGH FRACTURE TOUGHNESS MATERIALS

(71) Applicant: The University of Chicago, Chicago, IL (US)

(72) Inventors: Connor P. Horn, Chicago, IL (US); Supratik Guha, Chicago, IL (US)

(21) Appl. No.: 19/636,029

(22) Filed: Apr. 1, 2026

Related U.S. Application Data
(63) Continuation of application No. PCT/US2024/050097, filed on Oct. 4, 2024.
(60) Provisional application No. 63/587,886, filed on Oct. 4, 2023.
(60) Provisional application No. 63/556,965, filed on Feb. 23, 2024.

(51) Int. Cl. H10P 50/66; H10P 14/47; H10P 52/40

(52) U.S. Cl. CPC H10P 50/667; H10P 14/47; H10P 52/402

(57) ABSTRACT

The disclosure is directed to methods for spalling a substrate, products made by performing the methods, and apparatus and medium capable of performing the methods. One method includes obtaining a substrate; depositing a seed layer on the substrate; generating an edge around the seed layer for crack initiation in the substrate; and electroplating a stressor layer on the seed layer in an electroplating bath to spall the substrate to obtain a spalled substrate and a spalled film.

### RELATED APPLICATION

This application is a continuation application of PCT Patent Application No. PCT/US2024/050097, filed on Oct. 4, 2024, which is incorporated herein by reference in its entirety. The PCT Patent Application No. PCT/US2024/050097 is based on and claims the benefit of priority to U.S. Provisional Application No. 63/587,886 filed on Oct. 4, 2023 and U.S. Provisional Application No. 63/556,965 filed on Feb. 23, 2024, both of which are herein incorporated by reference in their entireties.

### GOVERNMENT LICENSE RIGHTS

This invention was made with government support under N00014-18-1-2869 awarded by the Office of Naval Research. The government has certain rights in the invention.

### BACKGROUND

Spalling a substrate is a technique for removing thin layers (films) from atop the substrate by triggered and propagation of a sub-surface crack across an entirety of the substrate. There are some issues/problems for spalling more refractory materials with a significantly higher fracture toughness (e.g., silicon carbide (SiC)).

The present disclosure describes various embodiments for spalling a substrate with high fracture toughness materials, addressing at least one of the issues/problems discussed above, leading to efficient spalling, and/or improving the technology field of spalling.

### SUMMARY

The present disclosure relates to methods, products, devices, and computer-readable medium for spalling a substrate; and apparatus and systems including a device made by spalling a substrate as described in the various methods.

In one embodiment, the present disclosure describes a method for spalling a substrate. The method includes obtaining a substrate; depositing a seed layer on the substrate; generating an edge around the seed layer for crack initiation in the substrate; and electroplating a stressor layer on the seed layer in an electroplating bath to spall the substrate to obtain a spalled substrate and a spalled film.

In some other embodiments, an apparatus/product comprising a film, wherein the film is made by spalling a substrate according to any of the methods above and/or in the present disclosure.

In some other embodiments, a system comprising an apparatus/product, wherein the apparatus/product comprises a film, and the film is made by spalling a substrate according to any of the methods above and/or in the present disclosure.

In some other embodiments, a device may include a memory storing instructions and at least one processing circuitry in communication with the memory. When the at least one processing circuitry executes the instructions, the at least one processing circuitry is configured to carry out a portion or all steps of the methods above and/or in the present disclosure.

In some other embodiments, a computer-readable medium comprising instructions which, when executed by a computer, cause the computer to carry out a portion or all steps of the methods above and/or in the present disclosure. The computer-readable medium may be a non-transitory computer-readable medium.

In some other embodiments, a computer program product comprising a computer-readable program medium code stored thereupon, the computer-readable program medium code, when executed by at least one processor, causing the at least one processor to implement a portion or all steps of the methods above and/or in the present disclosure. The computer program product may be a non-transitory computer program product. The computer-readable program medium code may be a non-transitory computer-readable program medium code.

The above and other aspects and their implementations are described in greater detail in the drawings, the descriptions, and the claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The system, device, product, and/or method described below may be better understood with reference to the following drawings and description of non-limiting and non-exhaustive embodiments. The components in the drawings are not necessarily to scale. Emphasis instead is placed upon illustrating the principles of the present disclosure.

FIG. 1 is a flow diagram of a method for spalling a substrate.

FIG. 2A is a schematic diagram of an exemplary method for spalling a substrate.

FIG. 2B is a schematic diagram of an exemplary method for spalling another substrate.

FIG. 3A is a schematic diagram of an exemplary embodiment of an edge for crack initiation.

FIG. 3B is a schematic diagram of another exemplary embodiment of an edge for crack initiation.

FIG. 3C is a schematic diagram of another exemplary embodiment of an edge for crack initiation.

FIG. 4 is a schematic diagram of an exemplary embodiment to generate the vertical edge in FIG. 3B.

FIG. 5 is a schematic diagram of an exemplary embodiment for electroplating a stressor layer.

FIG. 6 is a schematic diagram of an exemplary embodiment for a computer system (electronic device).

FIG. 7A shows mechanical properties and strain energy comparison of spalled substrates.

FIG. 7B shows minimum Nickle (Ni) stressor conditions for spalling different substrate materials.

FIG. 8 shows various exemplary embodiments including electroplating geometry and Ni thickness distribution.

FIG. 9A shows an exemplary embodiment including spalling crack initiation into 4H-SiC.

FIG. 9B shows an exemplary embodiment including details of Ni delamination during electroplating.

FIG. 9C shows a process flow diagrams of an exemplary embodiment.

FIG. 10 shows a picture of spalled 4H-SiC and remaining substrate of an exemplary embodiment.

FIG. 11 shows spalled 4H-SiC film and substrate surface morphology of various exemplary embodiments.

FIG. 12 shows heterogenous integration and substrate reuse of spalled 4H-SiC in various exemplary embodiments.

FIG. 13 shows comparison of 4H-SiC VV⁰ qubit properties between bulk wafer and spalled film in some exemplary embodiments.

FIG. 14A shows Ramsey spatial comparison from some exemplary embodiments.

FIG. 14B shows Ramsey spatial comparison after optimization of pulse parameters in some exemplary embodiments.

### DETAILED DESCRIPTION OF THE DISCLOSURE

The disclosed systems, devices, and methods will now be described in detail hereinafter with reference to the accompanied drawings that form a part of the present application and show, by way of illustration, examples of specific embodiments. The described systems and methods may, however, be embodied in a variety of different forms and, therefore, the claimed subject matter covered by this disclosure is intended to be construed as not being limited to any of the embodiments. This disclosure may be embodied as methods, devices, components, or systems. Accordingly, embodiments of the disclosed system and methods may, for example, take the form of hardware, software, firmware or any combination thereof.

Throughout the specification and claims, terms may have nuanced meanings suggested or implied in context beyond an explicitly stated meaning. Likewise, the phrase “in one embodiment” or “in some embodiments” as used herein does not necessarily refer to the same embodiment and the phrase “in another embodiment” or “in other embodiments” as used herein does not necessarily refer to a different embodiment. It is intended, for example, that claimed subject matter may include combinations of exemplary embodiments in whole or in part. Moreover, the phrase “in one implementation”, “in another implementation”, or “in some implementations” as used herein does not necessarily refer to the same implementation(s) or different implementation(s). It is intended, for example, that claimed subject matter may include combinations of the disclosed features from the implementations in whole or in part.

In general, terminology may be understood at least in part from usage in context. For example, terms, such as “and”, “or”, or “and/or,” as used herein may include a variety of meanings that may depend at least in part upon the context in which such terms are used. In addition, the term “one or more” or “at least one” as used herein, depending at least in part upon context, may be used to describe any feature, structure, or characteristic in a singular sense or may be used to describe combinations of features, structures or characteristics in a plural sense. Similarly, terms, such as “a”, “an”, or “the”, again, may be understood to convey a singular usage or to convey a plural usage, depending at least in part upon context. In addition, the term “based on” or “determined by” may be understood as not necessarily intended to convey an exclusive set of factors and may, instead, allow for existence of additional factors not necessarily expressly described, again, depending at least in part on context.

The present disclosure relates to methods for spalling a substrate and products that are fabricated by using such methods. The substrate may include materials having a significantly higher fracture toughness, for example silicon carbide (SiC). The product may be used to build a system, or be used as a part of a system. For non-limiting examples, the system may include SiC metal-oxide-semiconductor field-effect transistor (MOSFET) based inverter, a quantum device for quantum computing and/or information processing, and etc. In the present disclosure, the substrate may include but not limited to, single crystal substrates of 4H, 6H, and 3C silicon carbide, sapphire, aluminum nitride, and/or diamond. Various embodiments in the present disclosure may use semiconductor substrate (e.g., 4H polytype silicon carbide (4H-SiC)) as examples, which merely serve as examples and do not pose limitations; and various embodiments in the present disclosure may be applicable to substrate including other material(s) in similar manner.

The present disclosure, using single crystal 4H silicon carbide (4H-SiC) as a non-limiting example, describes various embodiments for enabling the controlled spalling of 10-50 micrometer (micron, μm) thick films of single crystal 4H-SiC from bulk substrates. 4H-SiC's properties, including high thermal conductivity and a wide bandgap, make it an ideal candidate for high-temperature, high-voltage power electronic devices. Moreover, 4H-SiC has been shown to be an excellent host of solid-state atomic defect qubits for quantum computing and quantum networking. Because 4H-SiC single crystal substrates are time consuming and difficult to grow, techniques for removal and transfer of layers in the tens-of-microns thickness range are highly desirable for substrate reuse and heterogenous integration of separated layers. In the present disclosure, novel approaches are utilized for stressor layer thickness control and spalling crack initiation to demonstrate controlled spalling of 4H-SiC, the highest fracture toughness material spalled to date. Additionally, substrate re-use, bonding of the spalled films to carrier substrates, and explore the spin coherence of the spalled films are demonstrated. In some implementations, coherent spin control of neutral divacancy (VV⁰) qubit ensembles is achieved and a spin T₂* of 0.581 microsecond (μs) is measured, approaching the bulk value of 1.35 μs.

In some embodiments, a controlled spalling method is utilized to obtain thin (10-50 micron) films/layers from atop a semiconductor substrate by triggered and deliberate propagation of a sub-surface crack across the entirety of the chip or wafer. Stress is built up in the wafer subsurface by the deposition of an appropriate metal (stressor) layer on the wafer surface. The crack originates at the wafer edge and then propagates laterally at a depth of 10-50 microns to relieve this stress without a need for post-conditioning (e.g. heat treatments). In some implementations, spall depth can be modulated by engineering the stress field via the metal film deposition. A significant benefit of spalling is that the bulk-like properties of the exfoliated film are preserved since the crack depth is determined by an elastic stress field, rather than an intervention by ion implantation or by the deposition of heterogeneous layers at the separation interface. In some implementations, a controllable method for spalling may be achieved by using nickel films deposited under high tensile stress via sputtering or electroplating.

In some implementations, the spalling method may be highly versatile, and may be used to spall Si, Ge, and III-V semiconductor wafers. Silicon wafers of up to 12 inches in diameter have been spalled. In some implementations, some of the materials that can be spalled may be semiconductors with moderate to low fracture toughness.

The present disclosure includes successful spalling of more refractory materials with a significantly higher fracture toughness. One such material with a significantly higher fracture toughness is the technologically important semiconductor, silicon carbide (SiC), particularly the 4H polytype. 4H-SiC high-power electronics are being increasingly adopted in electric vehicles (4H-SiC MOSFET based inverters) and photovoltaic power management (4H-SiC high power diodes). 4H-SiC is also a leading wafer scale candidate for solid state quantum coherent devices in quantum communications and sensing. Successful spalling of 4H-SiC creates two unique opportunities for this important semiconductor. First, a hindrance to further widespread adoption of 4H-SiC is the cost of manufacturing bare substrates. High intrinsic defect density, challenging polytype control, high temperatures, and long growth times contribute to low yields and high substrate cost. Spalling offers a pathway for reusing a substrate multiple times when the spalled device layer can be integrated onto other substrates. Second, such layer removal via spalling motivates the heterogeneous integration of 4H-SiC device layers with other materials, for example, to be particularly attractive for quantum technologies, where 4H-SiC has well characterized native defect based qubits with long coherence times, and these native defects may be located and spalled to be integrated with silicon based control electronics or embedded on photonic waveguides for applications in quantum communication.

In the present disclosure, a “film” may be a thin layer, for example, with thickness about 10 to 50 microns.

Various embodiments in the present disclosure shows spalling of 4H-SiC, wherein the challenge of spalling an ultrahard material is overcome which requires 2.5 times greater strain energy than needed to spall GaN, the previous hardest material to be spalled. Various methods in the present disclosure include novel scientific approaches taken in stressor layer design, spalling crack initiation, and/or controlled crack propagation, leading to a controlled spalling-based solution for layer removal and transfer of few tens-of-microns thick films of single crystal 4H-SiC from bulk substrates. In some implementations, bulk substrates may be then re-polished and be reused to spawn further films for removal and transfer. In some implementations, It is further shown that coherent spin control of a VV⁰ qubit ensemble in 4H-SiC with T₂* may have the same order of magnitude as in bulk substrates.

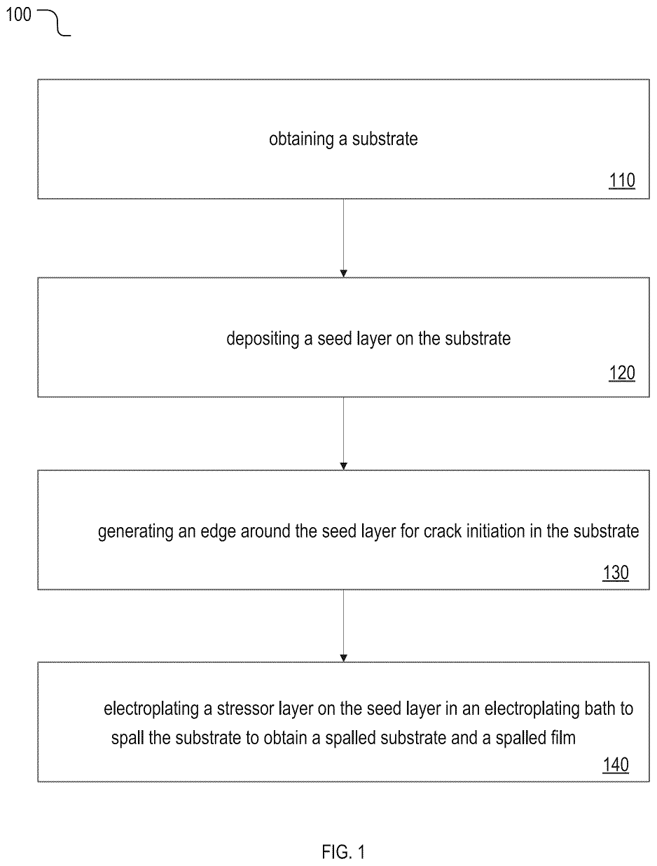

Referring to FIG. 1, the present disclosure describes various embodiments including a method 100 for spalling a substrate. The method may include a portion or all of the following steps: step 110, obtaining a substrate; step 120, depositing a seed layer on the substrate; step 130, generating an edge around the seed layer for crack initiation in the substrate; and/or step 140, electroplating a stressor layer on the seed layer in an electroplating bath to spall the substrate to obtain a spalled substrate and a spalled film. In some implementations, the substrate may be a single crystal substrate (e.g., single crystal semiconductor substrate or single crystal 4H-SiC substrate); and/or the spalled film may be a single crystal film (e.g., single crystal semiconductor film or single crystal 4H-SiC film).

In some implementations, a thickness of the substrate spans from 250 to 750 μm, inclusive.

In some implementations, the substrate comprises a single crystal substrate including at least one of the following: 4H, 6H, and 3C silicon carbide, sapphire, aluminum nitride, and/or diamond.

In some implementations, the seed layer is electrically conductive, and comprises at least one of the following elements: Cr, Ti, Au, Ta, W, Ni, or Pt.

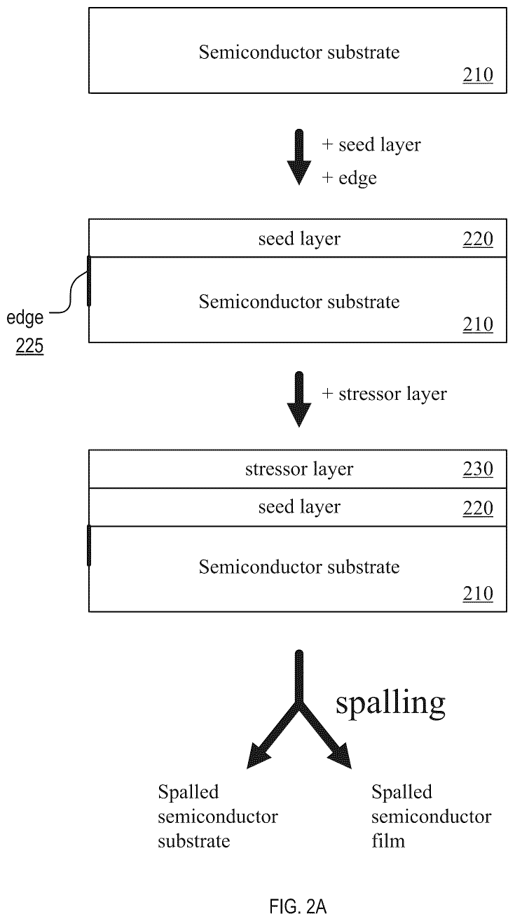

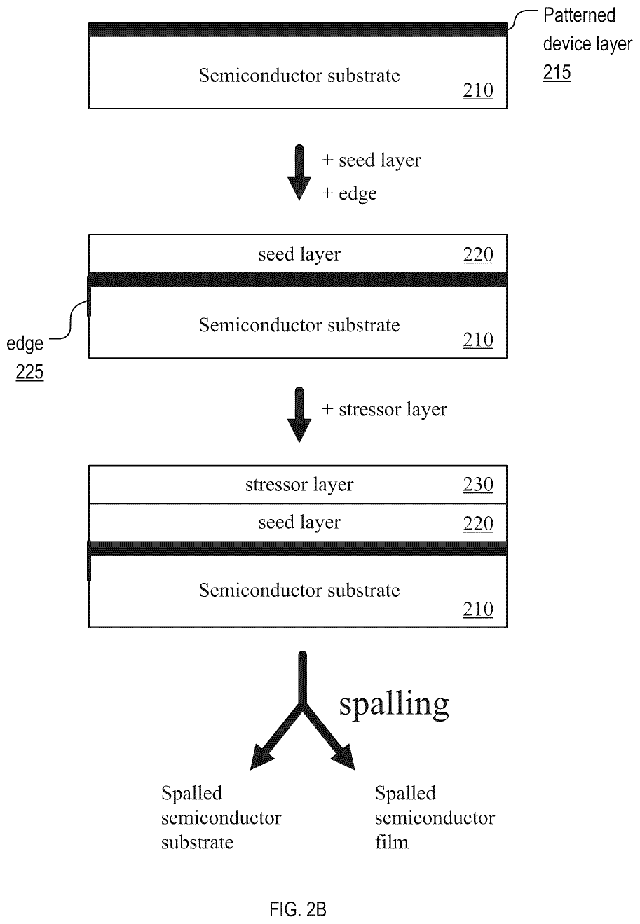

For a non-limiting example as shown in FIG. 2A, a substrate (e.g., a semiconductor substrate 210) may undergo a deposition process of depositing a seed layer 220 on top of the substrate to generate an edge 225, and then may undergo an electroplating process of electroplating a stressor layer 230 on top of the seed layer. After the semiconductor substrate is spalled, a spalled semiconductor substrate and a spalled semiconductor film/layer are obtained. In some implementations, the seed layer and/or the stressor layer may be removed from the spalled semiconductor film to expose its substrate.

In some implementations, before depositing the seed layer on the substrate, a patterned device layer is disposed on the substrate; and/or the depositing the seed layer on the substrate comprises depositing the seed layer on the patterned device layer. In some implementations, the patterned device layer comprises patterned metals and/or patterned dielectrics; and/or the patterned device layer is equal to or thinner than 10 μm. For a non-limiting example as shown in FIG. 2B, the semiconductor substrate 210 may be pre-fabricated with a layer of patterned devices 215. During the deposition process, the seed layer 220 may be deposited on top of the patterned device layer, and then the edge 225 is generated. During electroplating process, the stressor layer 230 is electroplated on the seed layer. After the semiconductor substrate is spalled, a spalled semiconductor substrate and a spalled semiconductor film/layer are obtained. In some implementations, the seed layer and/or the stressor layer may be removed from the spalled semiconductor film to expose its patterned device layer 215.

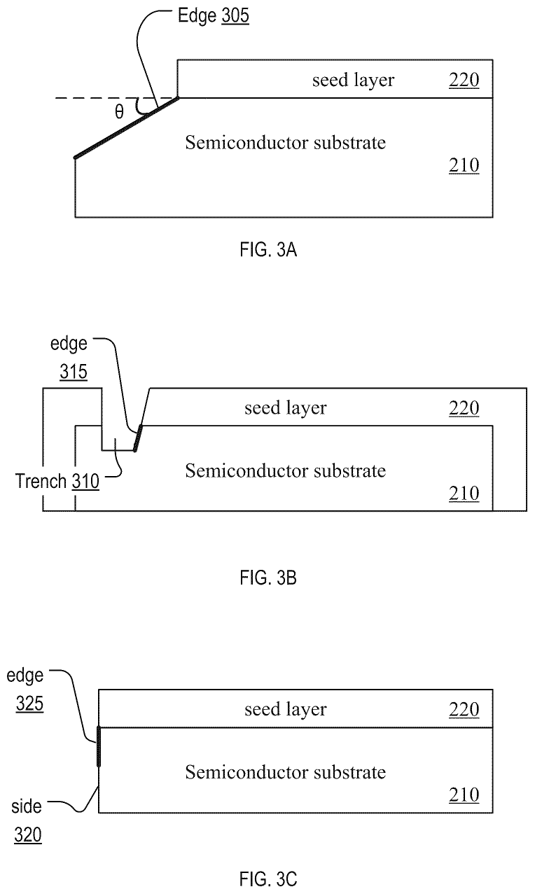

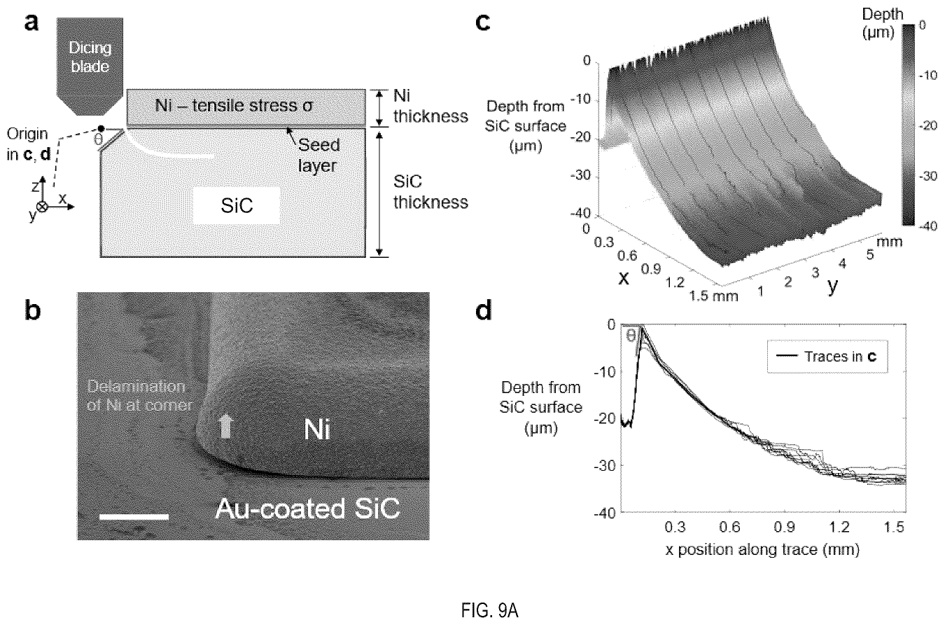

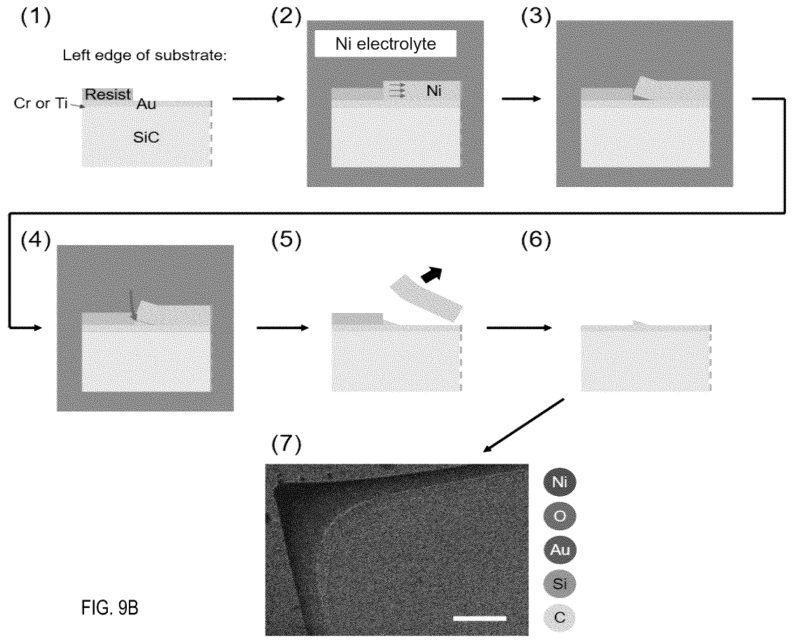

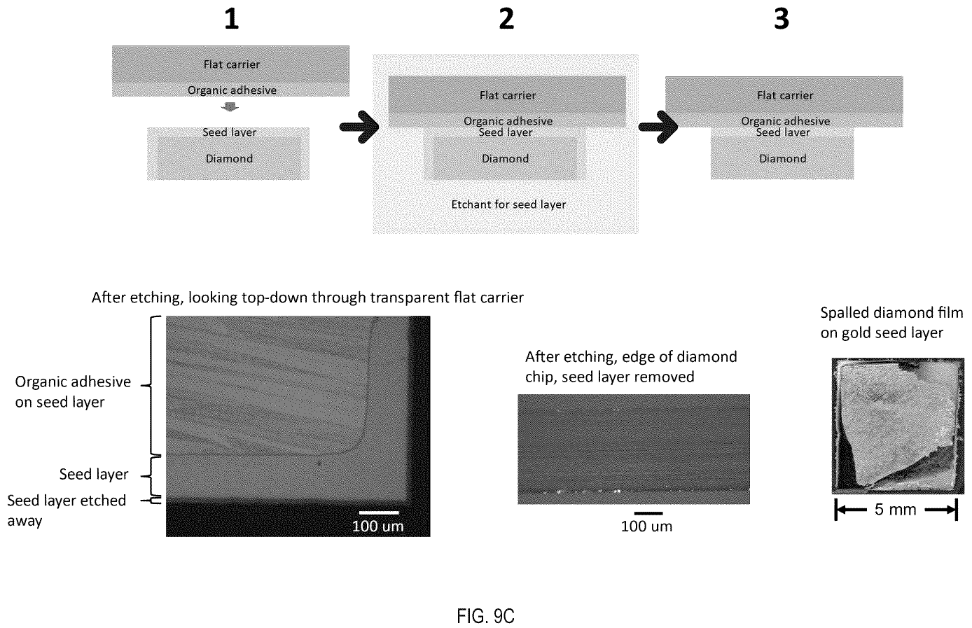

In some implementations, there may be at least one method for generating the edge around the seed layer for crack initiation in the substrate. For one example as shown in FIG. 3A, an edge 305 may be an (sloped) edge generated with a slope having a certain geometric shape such that an angle (θ) between a substrate's (210) horizontal surface and the edge slope at the termination of a seed layer (220) is larger than 0° and smaller than or equal to 90°. In some implementations, the edge has a geometry generated such that 0°<θ≤90°, wherein FIG. 3B shows one example of the angle being smaller than 90°, and FIG. 3C shows another example of the angle being 90° (i.e., an vertical edge). The structure of the edge is also described in FIG. 9A panel a.

For one method (trench method), the method may include disposing a trench at an edge of the seeding layer deep into the substrate to generate the edge around the seed layer for crack initiation. In some implementations, the trench is created with a dicing blade cut; and/or the trench is equal to or deeper than 5 μm. For a non-limiting example, referring to FIG. 3B, a trench 310 is generated to cut through a seed layer 220 and cut into a substrate 210 (e.g., semiconductor substrate), thus, generating an edge 315.

For another method (wet-etching method), the method may include wet-etching the seed layer at an edge of the seeding layer to generate the edge for crack initiation. For a non-limiting example, referring to FIG. 3C, a seed layer 220 at a side 320 may be wet-etched away from a substrate 210 (e.g., semiconductor substrate), thus, generating a (vertical) edge 325 with the angle being about or equal to 90°.

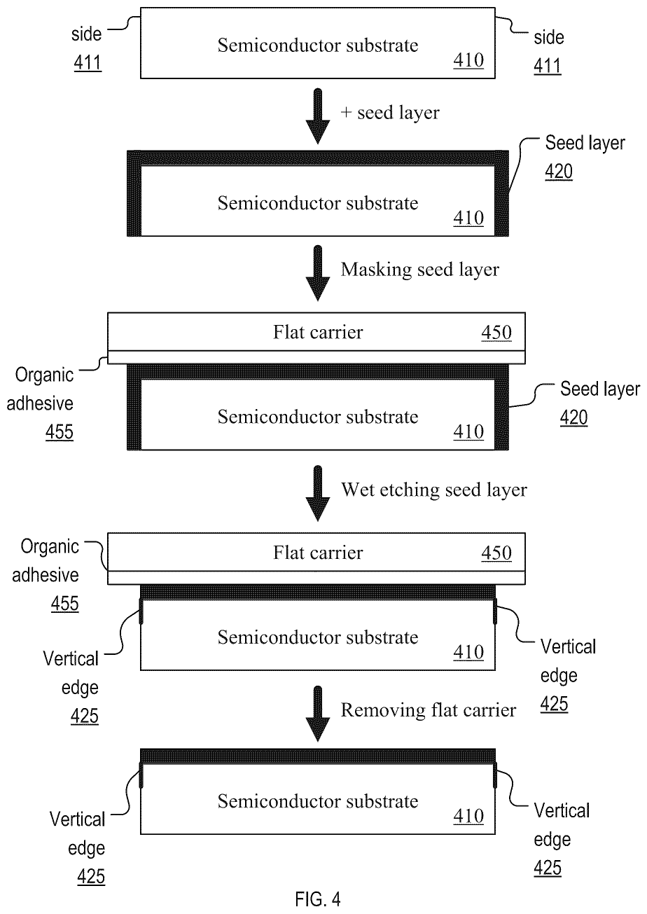

In some implementations, the method of wet-etching the seed layer may include a portion or all of the following: conformally depositing the seed layer on the substrate; masking the seed layer by disposing a flat carrier material with adhesive to bond a top surface of the seed layer; and/or using wet etchant to remove the seed layer from sides and around the edge of the substrate. For a non-limiting example, referring to FIG. 4, a substrate 410 (e.g., semiconductor substrate) may have sides 411. A seed layer 420 is conformally deposited on the substrate (on top and around the sides). The top of the seed layer 420 is masked by disposing a flat carrier material 450 with an adhesive layer 455 (e.g., an organic adhesive layer) to bond to the top surface of the seed layer. The whole apparatus is disposed in an etching bath using wet etchant to remove the seed layer from sides 411 of the substrate, thus resulting in edges 425, whose angles between the substrate's horizontal surface and the edge slope at the termination of a seed layer is about or equal to 90° (i.e., vertical edges). Then, the flat carrier 450 is removed from the seed layer, thus creating vertical edges.

In some implementations, the stressor layer comprises Ni.

In some implementations, the electroplating bath comprises at least one of the following: NiCl₂·6H₂0, CoCl₂·6H₂0, FeCl₂·4H₂0, FeCl₃·6H₂0, 30 g/L H₃BO₃, and/or NH₄Cl.

In some implementations, the step of electroplating the stressor layer on the seed layer in the electroplating bath may include electroplating the stressor layer on the seed layer in the electroplating bath with a current density with a range from 8 to 50 mA/cm², inclusive.

In some implementations, when electroplating the stressor layer on the seed layer in the electroplating bath, the method further includes disposing an auxiliary cathode between the seed layer and an anode in the electroplating bath for manipulate a thickness or uniformity of the stressor layer.

In some implementations, the auxiliary cathode is electrically shorted to the seed layer and is disposed an out-of-plane offset from the seed layer; and/or the auxiliary cathode is not radially symmetric. In some implementations, the auxiliary cathode has a flower-petal shape.

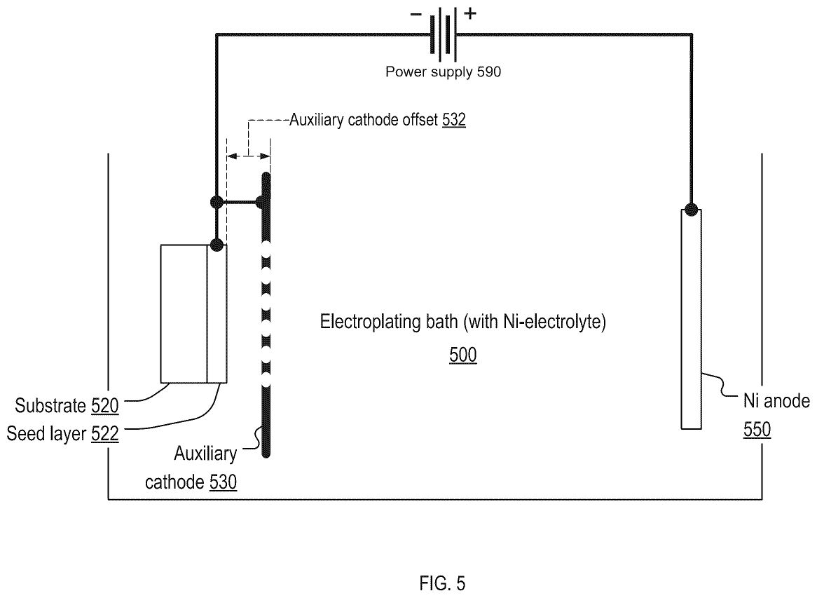

For a non-limiting example, referring to FIG. 5, a stressor layer (e.g., Ni) is electroplated onto a seed layer 522 on a substrate 520 in an electroplating bath 500 (e.g., with Ni-electrolyte to electroplate Ni onto the seed layer). The seed layer, serving as cathode, is electrically connected to a negative terminal of a power supply 590; and an anode 550 (e.g., Ni metal-plate) is electrically connected to a positive terminal of the power supply 590. An auxiliary cathode 530 may be disposed in front of the seed layer, i.e., between the seed layer and the anode. The auxiliary cathode is electrically connected with the seed layer directly (i.e., being short with the seed layer). A plane of the auxiliary cathode may be disposed at an offset 532 away from the seed layer. The offset, a size, and/or a shape of the auxiliary cathode may be adjusted to modify the electroplating thickness profile on the seed layer. For example, for a seed layer with 12 millimeter (mm) diameter, an auxiliary cathode may include a Cu plate with a ring shape having 13 mm inner diameter and 32 mm outer diameter, and an offset being 700 micrometer.

In some implementations, the method may include reusing the spalled substrate for subsequent spalling.

In some implementations, the reusing the spalled substrate for subsequent spalling may include a portion or all of the following: lapping a top surface of the spalled substrate to remove a divot from the spalled substrate; polishing the top surface of the spalled substrate; and/or subsequently spalling the spalled substrate.

In some implementations, the method may include bonding the spalled film onto a second substrate, wherein the second substrate comprises a single crystal substrate or polycrystalline substrate, comprising at least one of the following with undoped or doped with elements: silicon carbide, diamond, silicon, aluminum nitride, and copper.

In some implementations, a bonding layer is disposed between the spalled film and the second substrate; and the bonding layer comprises at least one of the following: laser-annealed metal-containing ohmic contacts, copper and/or its alloys, nonmetallic deposited films, hybrid metal particle and organic pastes, or organic pastes.

Various embodiments may include a stacked structure and/or process that includes a spalled material (e.g., SiC layer) and a handle substrate (e.g., a polycrystalline SiC or highly doped SiC), wherein that the spalled material is bonded to the handle substrate. In some implementations, the handle substrate may have a typical thickness ranging between 50 microns to a few or 10 mms, inclusive.

In some implementations, there may not be a bonding layer between the spalled material and the handle substrate.

In some implementations, the bonding between the spalled material and the handle substrate may be achieved via a combination of heat and pressure or simply heat application or simply pressure.

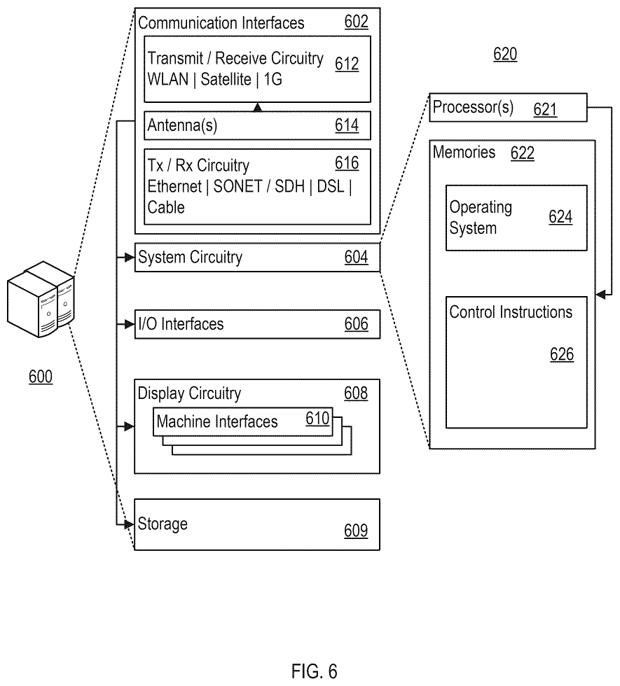

In various embodiments, a portion or all steps of the methods described in the present disclosure may be performed by various instruments that are controlled by a computer system (electronic device) 600, as shown in FIG. 6. The computer system (electronic device) 600 may include communication interfaces 602, system circuitry 604, input/output (I/O) interfaces 606, storage 609, and display circuitry 608 that generates machine interfaces 610 locally or for remote display, e.g., in a web browser running on a local or remote machine. The machine interfaces 610 and the I/O interfaces 606 may include GUIs, touch sensitive displays, voice or facial recognition inputs, buttons, switches, speakers and other user interface elements.

The machine interfaces 610 and the I/O interfaces 606 may further include communication interfaces with modulators, sensors, and/or detectors. The communication between the computer system 600 and the sensors and detector may include wired communication or wireless communication. The communication may include but not limited to, a serial communication, a parallel communication; an Ethernet communication, a USB communication, and a general purpose interface bus (GPIB) communication. Additional examples of the I/O interfaces 606 include microphones, video and still image cameras, headset and microphone input/output jacks, Universal Serial Bus (USB) connectors, memory card slots, and other types of inputs. The I/O interfaces 606 may further include magnetic or optical media interfaces (e.g., a CDROM or DVD drive), serial and parallel bus interfaces, and keyboard and mouse interfaces. The quantum-classical interface may include an interface communicating with a quantum computer.

The communication interfaces 602 may include wireless transmitters and receivers (“transceivers”) 612 and any antennas 614 used by the transmitting and receiving circuitry of the transceivers 612. The transceivers 612 and antennas 614 may support Wi-Fi network communications, for instance, under any version of IEEE 802.11, e.g., 802.11n or 802.11ac. The communication interfaces 602 may also include wireline transceivers 616. The wireline transceivers 616 may provide physical layer interfaces for any of a wide range of communication protocols, such as any type of Ethernet, data over cable service interface specification (DOCSIS), digital subscriber line (DSL), Synchronous Optical Network (SONET), or other protocol. In another implementation, the communication interfaces 602 may further include communication interfaces with the modulators, sensors, and/or detectors.

The storage 609 may be used to store various initial, intermediate, or final data. In one implementation, the storage 609 of the computer system 600 may be integral with a database server. The storage 609 may be centralized or distributed, and may be local or remote to the computer system 600. For example, the storage 609 may be hosted remotely by a cloud computing service provider.

The system circuitry 604 may include hardware, software, firmware, or other circuitry in any combination. The system circuitry 604 may be implemented, for example, with one or more systems on a chip (SoC), application specific integrated circuits (ASIC), microprocessors, discrete analog and digital circuits, and other circuitry. For example, the system circuitry 604 may include one or more instruction processors 621 and memories 622. The memories 622 stores, for example, control instructions 626 and an operating system 624. In one implementation, the instruction processors 621 execute the control instructions 626 and the operating system 624 to carry out any desired functionality related to the controller.

The electronic device in the present disclosure described in the present disclosure may be implemented by a portion or all of the computer system 600 as described above. In some implementations, a portion of steps or all steps in various methods described in the present disclosure may be implemented by a portion or all of the computer system 600.

The present disclosure describes various exemplary embodiments for spalling a substrate (e.g., semiconductor substrate), and the exemplary embodiments merely serve as examples and do not pose limitations. Any steps and/or operations in one same embodiment/implementation or more than one different embodiments/implementation in the present disclosure may be combined or arranged in any amount or order, as desired. Two or more of the steps and/or operations may be performed in parallel. Embodiments and implementations in the disclosure may be used separately or combined in any order. Further, a portion or all of the methods (or embodiments) may be implemented by processing circuitry (e.g., one or more processors or one or more integrated circuits).

In various embodiments, prior to spalling, a film of metal (the stressor layer) is deposited onto the wafer to be spalled such that stresses in the metal layer give rise to an elastic stress field in the wafer sub-surface region. The higher the fracture toughness of the wafer to be spalled, the higher the thickness and stress of the metal film required to induce steady state spalling. A theoretical model may be valuable for predicting the required thickness and stress of the metal film for spalling and enable calculation of the stress intensity factors K_{I} and K_{II} of a propagating crack within the substrate. With respect to the spalling stress intensity factors versus depth in the substrate, the crack originates at a free surface (usually the top surface of the semiconductor wafer) and propagates as a mixed mode crack (non-zero values of K_{I} and K_{II}) plunging into the semiconductor. At a specific depth when K_{II}~0, the crack propagates in a direction that is on average parallel to the surface and spalls off a film of the semiconductor substrate attached to the metal stressor layer.

In some implementations, there is one additional condition that must be met to enable successful spalling which is limited by the semiconductor material's intrinsic fracture toughness (K_{IC}). This requirement originates from the Griffith criterion, which postulates that a crack can propagate if the release of strain energy in a stressed system is greater in magnitude than the energy cost of creating two free surfaces because of the crack. A critical strain energy release rate Gc needed to propagate a crack in a material may be defined as

$${G}_{C} = \frac{{K}_{IC}^{2}}{E ( 1 - {v}^{2} )}$$

wherein E is the Young's modulus and v is the Poisson's ratio of the crack propagation medium.

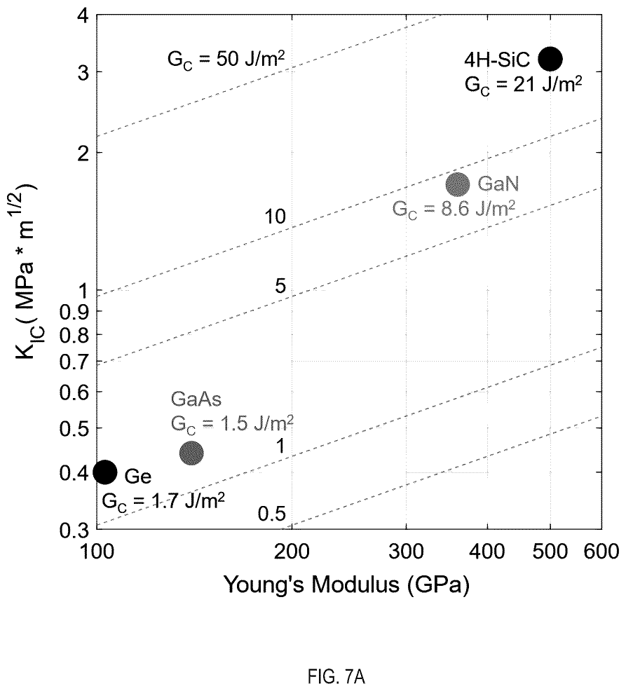

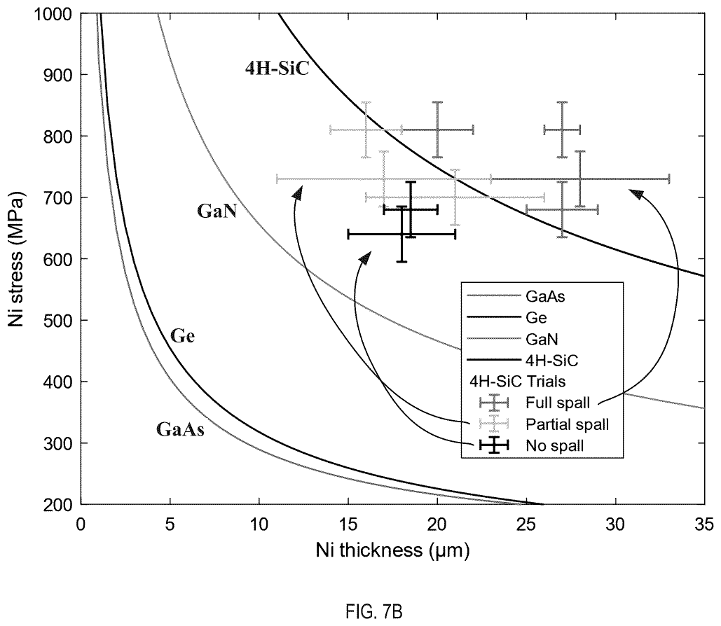

With regards to spalling, the solution for Gc in above equation serves as a figure of merit for defining the strain energy per unit area required for spalling a semiconductor with a given K_{IC}, E, and v. The semi-log Ashby plot in FIG. 7A illustrates the strain energy required for spalling 4H-SiC as compared to various materials. GaN was previously the most challenging material that had been spalled, whereas the 4H-SiC spalling may require almost 2.5 times more strain energy. FIG. 7B shows details on the required Ni metal films needed to achieve these strain energies for the selected materials. This previously unexplored level of strain energy per unit area applied to the metal-semiconductor spalling system poses new challenges critical to spalling of hard materials, notably (i) the thickness distribution of the metal film and (ii) the spalling crack nucleation. The scientific approaches used to address and overcome these challenges are described in the present disclosure and may be applicable to the spalling of many other high fracture toughness semiconductors beyond 4H-SiC. As addressed below, some of key materials issues relevant to the spalling of such ultra-hard materials.

FIG. 7A shows mechanical properties and strain energy comparison of spalled substrates. The Ashby map depicts the mechanical properties of previously spalled substrate materials alongside 4H-SiC. The dashed lines are equipotential GC energies, plotted using above equation. In some implementations, the Poisson's ratio used for the equipotential lines was 0.25, an average value among these semiconductors.

FIG. 7B shows minimum Ni stressor conditions for spalling different substrate materials. The curves for GaAs, Ge, and GaN are fit to the Suo and Hutchinson mathematical model using data and extracted material properties found in previous spalling work and independent experiments. These curves represent the critical minimum Ni thickness and stress needed for controlled spalling. The 4H-SiC curve is also fit to the Suo and Hutchinson model; the Young's modulus (500 GPa) and Poisson's ratio (0.16) are chosen as average values from literature and the fracture toughness (3.20 MPa m^{1/2}) is fit so that the curve agrees with the experimental results. Other relevant material properties used in fitting the curves include the Young's modulus of Ni (200 GPa) and the Poisson's ratio of Ni (0.31). All substrate thicknesses were set to 1000 μm to reflect that the substrates are held down either with double sided tape or a vacuum chuck, therefore increasing this variable to near-infinite. The experimentally determined 4H-SiC fracture toughness of 3.20 MPa m^{1/2} agrees well with a study on 4H-SiC single crystals using indentation tests, which reports fracture toughnesses ranging from 3.15 MPa m^{1/2} to 3.33 MPa m^{1/2} for indentations on the prismatic (101̅0) and basal (0001) planes, respectively.

In some implementations, data from the experimental results in the present disclosure is plotted using error bars with various shades. Ni thickness was determined by plating time and stress was modulated as defined in the methods section. In many cases, numerous trials were run at a particular condition, but are not plotted to avoid crowding the plot with duplicate information. Ni thickness was measured with a 3D laser scanning confocal microscope to <0.5 μm accuracy. The wider thickness ranges in the plot represent the nonuniformity in Ni electroplating thickness on the substrate, specific to the electroplating parameters for each trial. Since Ni stress/wafer bowing could not be accurately measured on the small square-shaped samples, proxy measurements were done in a secondary plating bath using the bent strip method (e.g., ASTM Standard B975). Various bath chemistries and current densities were characterized and a standard deviation of 23 MPa was calculated. Error bars for the Ni stress are plotted to include two standard deviations above and below the mean, to reflect a 95% confidence interval. The relatively large (~90 MPa) confidence interval also accounts for an observed day-to-day variability in Ni stress potentially due to several factors including changes in pH, NH₄Cl concentration, temperature, contamination, etc. The Suo and Hutchinson curve for 4H-SiC is fit so that it completely encapsulates the fully spalled cases and encapsulates approximately a quarter of the partially spalled Ni thickness range, while excluding all the no-spall cases.

### Thickness Distribution of the Stressor Layer

In various embodiments, the thickness distribution of the (metal) stressor layer holds considerable influence over the outcome of the controlled spalling process. The spalling fidelity of 4H-SiC may be unpredictable when the thickness of the stressor layer at the substrate edges versus the substrate center varies by more than 10% from the intended distribution. This is because the necessary G>GC fracture conditions required for crack initiation and crack propagation (see other portions of the present disclosure) are generally independent and must be kept in balance to yield a controlled spall.

In various embodiments, the electroplated metal may include Nickel (Ni). Electroplated nickel has been used extensively as the metal of choice for spalling due to the availability of well characterized plating techniques, high deposition rate, and the ability to precisely control Ni stress through plating conditions. Although thickness uniformity can be excellent for sputtered Ni as compared to electroplating, the deposition rate (~2 μm/hour) and maximum tensile stress (700 MPa) of sputtered Ni are undesirable and unacceptable, respectively, to attain the >20 μm thickness and ~700-850 MPa stress needed to spall 4H-SiC (see FIG. 7B). These stress levels have been demonstrated via electroplating of Ni, but additional considerations are needed for ensuring desirable thickness distribution of the plated layer. The present disclosure describes methods for addressing a known aspect of electroplating called “current crowding” in which the deposit on the wafer edges can be up to 2-3 times thicker than the deposit thickness at the center.

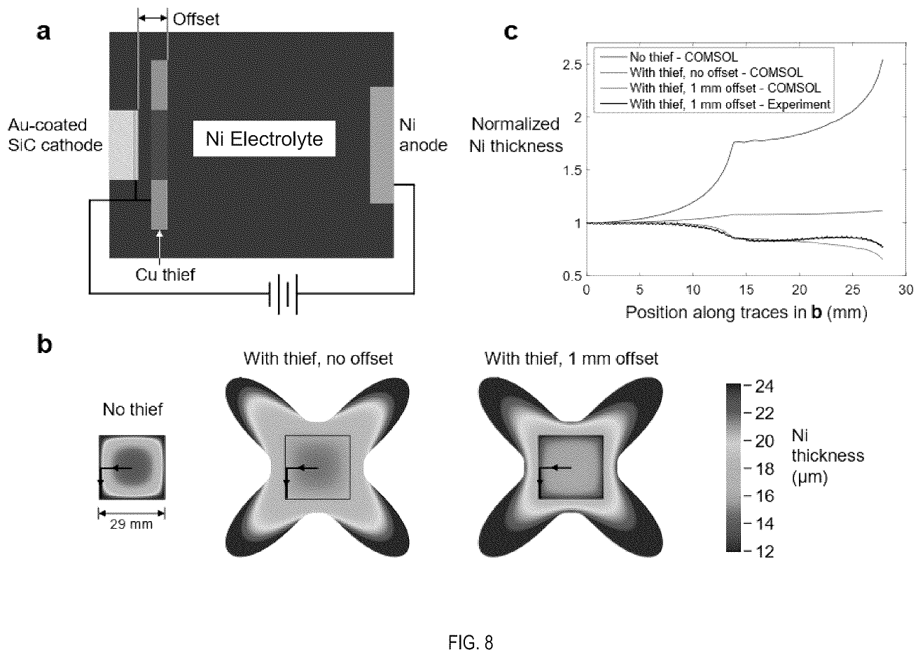

In some implementations, to address the problematic thickness nonuniformity of electroplated Ni, an auxiliary cathode which is known in the electroplating industry as a “thief” may be designed and integrated into the electroplating setup. The thief adds additional surface area to the cathode and draws current density away from the edges of the target substrate. Panel c of FIG. 8 shows a diagram of the electroplating bath with the thief shorted to and coaxially offset from the Au-coated 4H-SiC cathode. Further details of the Au coating and Ni electroplating procedure are described in other portions of the present disclosure. An iterative design process for the thief utilized finite element modeling in COMSOL to simulate the Ni electroplating thickness profiles on a 29×29 mm square substrate (typical size of 4H-SiC die) as a function of the size, shape, and position of a conductive thief surrounding it.

In some implementations, after iteratively tuning the thief position and the parametric curve which describes the outer perimeter of the thief, the findings were twofold: (1) the Ni thickness at the absolute center versus the edges of the target 4H-SiC substrate could be tuned such that the edges could be at least a factor of 1.5 thicker or thinner than the center, and (2) the Ni thickness around the edges of the square substrate could be independently controlled by at least that factor at any segment along the perimeter. With regards to (1), by adjusting the offset between the thief and 4H-SiC substrate, the colormaps in panel B of FIG. 8 and the accompanying profiles in panel c of FIG. 8 reveal that the Ni thickness at the absolute center of the square 4H-SiC substrate can be made thicker or thinner than the Ni thickness at the edges depending solely on the thief offset. With regards to (2), the thief design may account for the intrinsic dissimilarity in the electroplating current density at the corners versus the edge centers of the square substrate and negate the stronger electric field at the corners by increasing the plate-able surface area near the corners. The chosen “flower” shape as shown in panel B of FIG. 8 completely alters the Ni thickness profile along the square perimeter from the “no thief” case. Other options are possible with different size “petals” on the flower-shaped thief. Smaller petals make the corners thicker than the edge centers, and larger petals do the opposite.

For a non-limiting example, the depicted thief shape with a 1 mm offset may be chosen to result in the Ni thickness hierarchy as following: center of chip>edge centers>corners. This scheme was chosen subsequent to the observation that square substrates nearly always start spalling from the corners, so if the corners are the last regions to reach the critical Ni thickness required for spalling, the rest of the substrate will already have sufficient stress from the Ni to easily propagate the spalling crack.

FIG. 8 shows electroplating geometry and Ni thickness distribution in various embodiments. Panel a shows a top-down schematic of the electroplating geometry. The opening in the thief exactly matches the square shape of the SiC cathode. Panel b shows a COMSOL simulated Ni electroplating thickness distribution on 29 mm×29 mm square substrates with and without thieves. Outer areas of the thieves exceed the plotted thickness range which is capped at 24 μm for better height resolution on the SiC surface. Current density averages 9 mA/cm2 on the SiC surface in all three cases. Panel c shows simulated and experimental measurements of Ni thickness along the traces in panel b. Values are normalized so that the thicknesses at the center of the substrates are coincident on the plot.

### Spalling Crack Nucleation

Various embodiments include methods to address another concern for spalling, which is specific to ultrahard materials is that crack initiation—the prerequisite to steady state spalling—was found to be near impossible using pre-established controlled spalling techniques. The conventional method by which spalling crack initiation is made into Si and other semiconductors of similar toughness is to make the Ni abruptly discontinuous away from the substrate edge. The stress concentration where the edge of the Ni meets the substrate is then high enough such that a crack can initiate either spontaneously when a certain Ni thickness is reached, or with external force from a handle layer of tape which is applied on top of the Ni and pulled upwards. For Si and other mechanically similar materials, no modification of the substrate is needed to initiate a spalling crack, meaning that θ=0 as defined by the diagram in panel a of FIG. 9. For 4H-SiC however, it is found that crack initiation using this technique is nearly impossible. Instead of inducing a spalling crack, the Ni may delaminate from the Cr/Au or Ti/Au seed layer which is used a conducting layer to promote adhesion between the semiconducting substrate and the electroplated Ni. It is observed that Ni delamination from the Au was the common failure mechanism when utilizing the conventional spalling crack initiation method on 4H-SiC substrates.

In some implementations, the adhesion between the 4H-SiC and the Cr or Ti was consistently observed to be quite strong and was rarely a source of delamination as long as the starting 4H-SiC surface was cleaned properly as described in the methods section. Moreover, the delamination of the Ni precisely at the Au—Ni interface was unexpected because the bond dissociation energy of the Au—Ni bond is 247 kJ/mol while the bond dissociation energy of the Au—Au bond is actually weaker at 225 kJ/mol, meaning that the delamination was likely triggered by the geometry of the layers rather than chemical bond strength. Panel b of FIG. 9A shows a scanning electron microscope (SEM) image of electroplated Ni which has been made discontinuous away from the substrate edge according to conventional spalling methodology. The resist from patterning has been removed to reveal that the corner of the Ni is visibly lifting off the Au-coated 4H-SiC substrate, rather than propagating a crack downwards. In fact, it is discovered that during electroplating, the deposited Ni re-fills the gap that opens between the Au and the delaminating Ni film, as presented in FIG. 9B. Although this prolongs the time until the Ni film fully delaminates, it is not enough to change the preference for delamination instead of spalling. Thus, a solution was needed to modify the local stress intensity where the edge of the Ni meets the 4H-SiC to properly initiate spalling.

FIG. 9A shows spalling crack initiation into 4H-SiC. Panel a shows a diagram showing the spalling geometry for crack initiation and propagation. Panel b shows a SEM image of Ni stressor layer beginning to delaminate from the Au-coated 4H-SiC substrate, wherein the scale bar is 20 μm. Panel c shows a 3D laser scanning confocal microscope map taken at the crack initiation edge of a 4H-SiC substrate after spalling. Trench for crack initiation is present from x=0 to 0.15 mm, beyond which the spalling crack is mapped. Panel d shows that black line traces on the 3D map in panel c are merged and plotted as spall depth versus x position. Trench angle θ is measured to be 29 degrees.

FIG. 9B shows details of Ni delamination during electroplating. During electroplating of the Ni layer, which is under a high intrinsic tensile stress, the Ni may partially delaminate around the perimeter of the area it is covering. However, when that delamination happens between metal surfaces (in this case the Ni and the Au from the sputtered seed layer), Ni ions may re-deposit into the wedge which opens up underneath the delaminating Ni. This re-deposition effect prolongs and can even eliminate the possibility of full delamination of the Ni from the Au-coated 4H-SiC substrate. The timeline is as the following. (1) Polymer resist is applied on the perimeter of the Au-coated 4H-SiC substrate to electrically mask the Ni plating and define the edge of the Ni where the spalling crack should initiate. (2) Ni is electroplated onto the substrate, and the high intrinsic tensile stress of the Ni (three arrows indicate direction) causes (3) the Ni to slightly delaminate from the Au at the edge. Where the Ni lifts off the Au, (4) a new deposit of Ni forms on the exposed Au surface. (5) If the plated Ni film is peeled off/fully delaminates, the Ni deposit on the newly exposed gold remains, appearing to have better adhesion to the Au than the underside of the Ni film. (6) The resist is washed away and (7) the elements on remaining surface are characterized via an energy dispersive X-ray spectrometer (EDS) in a scanning electron microscope (SEM) (e.g., JEOL IT800HL) and analyzed using a software (e.g., Oxford Instruments AZtec software). The graduated Ni deposit around the perimeter of the corner is due to the original Ni film lifting up at the edges and new Ni plating on the Au underneath. The oxygen is from the native oxide on the Ni, and the Si and C from the 4H-SiC substrate are detectable through the Au layer. The Cr from the seed layer is too thin to be detected.

In some implementations, this crack initiation problem may be solved by modifying the 4H-SiC substrate such that θ>0 as defined in panel a of FIG. 9A. In practice, it may be chosen to cut a shallow trench at the edge of the 4H-SiC substrate with a standard dicing saw after seed layer deposition. By adjusting the cut depth, it's able to achieve θ angles from 8 to 90 degrees and initiate spalling at the top surface of the 4H-SiC substrate directly adjacent to the trench. Panel c and d of FIG. 9A depict 3D and 2D laser confocal microscope scanned surface profiles at the crack initiation edge of a spalled 4H-SiC substrate with 0=29 degrees. The trench spans from x=0 to 0.15 mm, and then for x>0.15 mm the spalling crack starts from the very top of the 4H-SiC surface and subsequently plunges downward into the substrate until the equilibrium spall depth is reached. This method of inducing a spalling crack with an angled trench appears to defy other relevant studies on crack initiation at the edge of stepped boundaries which suggest that as compared to larger θ angles, θ=0 should concentrate the KI stress intensity most highly where the edge of the Ni meets the substrate and most strongly favor crack initiation. Yet it is observed that spalling crack self-initiation occurs when the electroplated Ni adjacent to the trench cut reaches a predictable and constant critical thickness regardless of the depth or angle of the trench, but not at all if there is no trench cut. One possible explanation is that by removing material from the 4H-SiC adjacent to the edge of the Ni, the total strain energy needed to laterally separate the 4H-SiC substrate is decreased. Therefore, a crack can more readily overcome the energy barrier of initially separating a few substrate atoms on the 4H-SiC surface to start a spalling crack. Once the crack has been initiated, it propagates through the 4H-SiC substrate according to the approach utilized for controlled crack propagation.

In some implementations, diamond generally may not be cut using a standard dicing saw. An alternative method to generate an edge for crack initiation is to conformally deposit the seed layer on the ultrahard substrate, and then selectively wet etch the seed layer away from the sides. FIG. 9C shows a process flow diagrams of an exemplary embodiment, which may be accomplished by bonding the top surface of the ultrahard substrate to a flat carrier material to mask this area from the wet etchant. Then the heterostructure is placed into the wet etchant to remove the seed layer from the sides. As shown in FIG. 9C, this can ensure that the seed layer will extend to within 20 microns of the edge of the ultrahard substrate and is fully etched away from the sides. This enables a spalling crack to be initiated in diamond, demonstrating the spalling of diamond.

### Physical Characterization of Spalled Substrates and Films

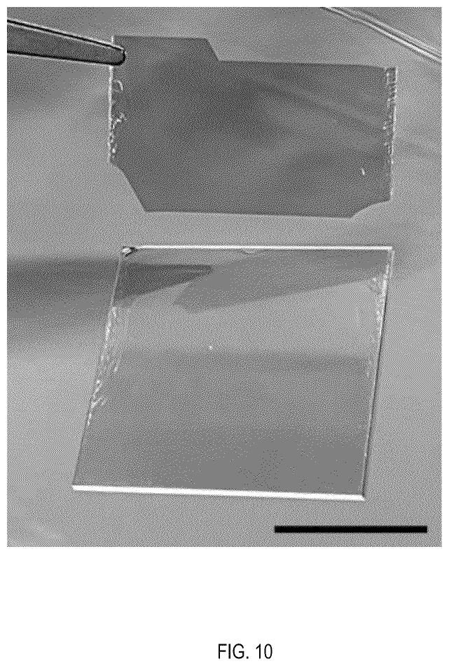

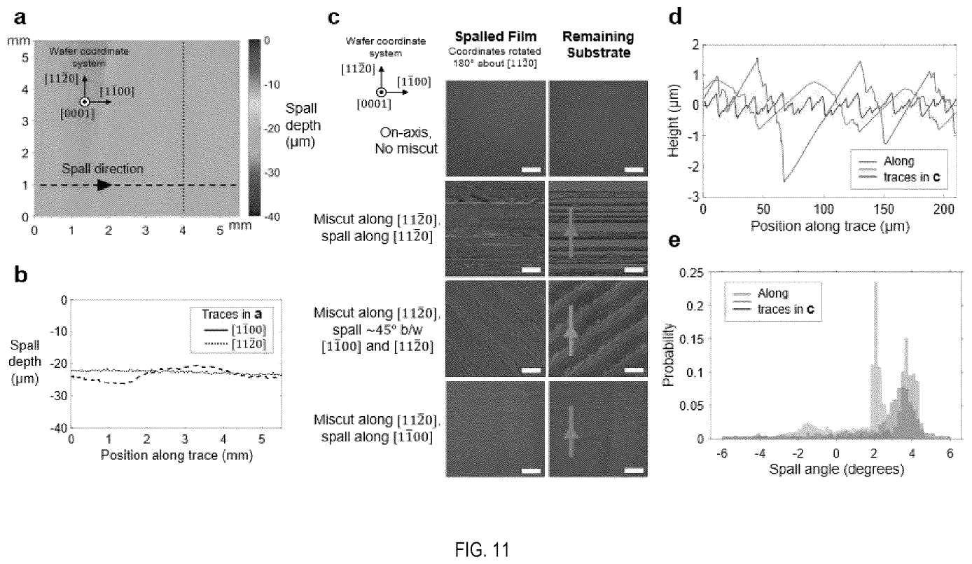

In some implementations, the 4H-SiC substrates spalled may have various sizes, for non-limiting examples, ranging from 5×5 mm to 29×29 mm squares cut from 4- or 6-inch wafers. The decision to spall square dies instead of full wafers reflects the high cost of 4H-SiC wafers and not any anticipated new challenges with spalling larger substrates. In fact, observation of the spalled substrate and film in FIG. 10 reveals that there are often ~2 mm wide edge effects on the perimeter of the spalled dies, so the spalling of larger wafers is more desirable to maximize usable area. To further explore the surface morphology of spalled 4H-SiC, a 3D laser scanning confocal microscope was used to profile spalled substrates at different length scales in FIG. 11. In panels a and b of FIG. 11, a 5.5×5.5 mm area near the center of a spalled substrate is investigated. The profiles reveal that spall depth along the direction of crack propagation ([11̅00]) is more variable than spall depth perpendicular to the direction of crack propagation ([112̅0]). The [11̅00] profile shows an undulation of approximately 5 μm in spall depth, implying slight fluctuation in the speed or angle of crack propagation which in turn causes the crack tip to undulate. For applications which require a more homogenous spall thickness, a mechanical system can be adopted to better control the spalling crack speed and angle to improve this nonuniformity.

FIG. 10 shows a picture of spalled 4H-SiC and remaining substrate. The ~30 μm thick spalled film is held with a tweezer above the corresponding substrate which it originated from. The film was fully intact when it spalled from the substrate, wherein the scale bar is 15 mm.

FIG. 11 shows spalled 4H-SiC film and substrate surface morphology. Panel a shows 3D laser scanning confocal microscope map of the surface of a remaining substrate after spalling. Absolute spall depth and tilt are calibrated by deliberately un-spalled regions outside the boundaries of the map shown. Wafer coordinate system shown assumes a non-miscut crystal. Panel b shows profiles of spall depth versus position for the line traces in panel a. Panel c shows optical differential interference contrast images of various spalled films and substrates. Blue, green, and red colored traces indicate the scan direction of the profiles in panel d. Wafer coordinate system shown assumes a non-miscut crystal. Scale bars, 100 μm. Panel d shows laser scanning confocal microscope profiles of spall depth variation versus position for the line traces in panel c, centered about the mean surface heights. Panel e shows histogram of the instantaneous slopes for all data points in the curves from panel d. Bins are 0.2 degrees wide and instantaneous slopes are takes over 1.1 μm intervals with 0.28 μm step size.

In some implementations, doped 4H-SiC used in power electronics is often grown with a 4-degree miscut to the c-axis, such that the surface normal is tilted 4 degrees from [0001] towards [112̅0]. While miscut substrates are most common, on-axis 4H-SiC is also common in radio frequency (RF) applications. It is observed that the on-axis spalled surfaces were visibly smooth, as pictured in panel c of FIG. 11. When spalling the miscut substrates, matching corrugations were observed on the surfaces of the remaining substrates and spalled films, with amplitude and spall angle dependent on spall direction as plotted in panel d of FIG. 11. The perpendicular-to-miscut spall ([11̅00] spall direction) had the lowest roughness: the mean±standard error of the maximum peak-to-peak height measured across ten line profiles was 0.927±0.015 μm. Referring to panel e of FIG. 11, the angles of upward crack propagation for the different spall directions are bunched together under the influence of the angled (0001) planes. The parallel-to-miscut spall is predictably angled at 4 degrees, while the 45°-to-miscut spall incurs two factors of 1/\sqrt{2} from the rotated spall angle and rotated facet angle both relative to [112̅0]. Interestingly, the perpendicular-to-miscut spall is dissimilar in that the facets exhibit an unpredictable and wider distribution of spall angles as compared to the other cases.

In some implementations, semiconductors with high ionicity tend to spall along specific crystal planes, whereas elemental semiconductors may not be as bound to this tendency. For example, GaAs only spalls along {110} planes, such that the surface of spalled (100) GaAs exhibits a sawtooth-like appearance with peak-to-peak variation approximately equal to the spalled layer thickness. (100) Si on the other hand, despite {110} and {111} being the preferred cleavage planes, can be spalled with less than 100 nm surface roughness. Despite being made up of two group 4 atoms, SiC actually has more ionic character than GaAs (electronegativity difference 0.7 for SiC and 0.5 for GaAs), meaning that 4H-SiC should also be expected to highly bound to spalling along specific planes. In this work, on-axis (0001) 4H-SiC and on-axis (1010) 4H-SiC were both spalled and found to yield smooth corrugation-free surfaces, establishing that both of these slip systems exhibit favorable cleavage for spalling. The asymmetry in spall angle caused by the 4-degree miscut (see FIG. 11 panel e) allows for observation of the downward crack path propagation which has no preferred spalling plane. Despite the asymmetry in spall angle, in all cases the crack path produces nearly symmetric sawtooth-like profiles (see FIG. 11 panel d).

### Substrate Re-Use and Integration of Spalled Films on Carrier Substrates

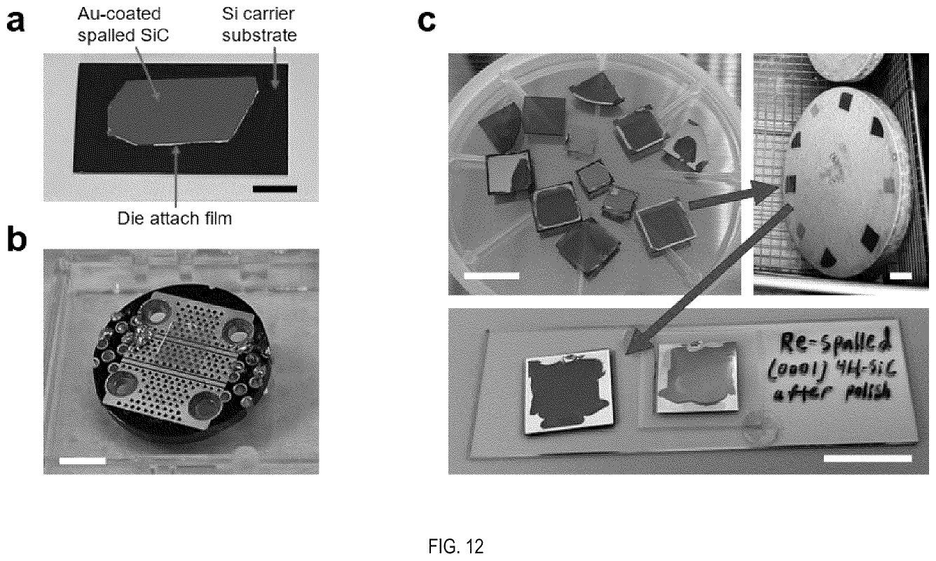

In some implementations, substrate re-use and heterogeneous integration are the main motivations for spalling. The present disclosure may primarily focus towards identifying conditions for 4H-SiC spalling, and the present disclosure also includes some initial demonstrations. To demonstrate substrate re-use, a selection of previously spalled substrates was subjected to a standard lapping and chemical mechanical polishing procedure for 4H-SiC to remove the divot from the spalled surface and polish it back to its original condition. The substrates were then re-spalled to establish that there are no unforeseen problems caused during surface reconditioning which would otherwise prevent further spalling. In total, the thickness reduction of the initial 4H-SiC substrate due to spalling and re-polishing can be limited to the maximum spall depth+approximately 15 to 20 μm due to the lapping and polishing process. Images of the repolished and re-spalled substrates are included in FIG. 12.

FIG. 12 shows heterogenous integration and substrate reuse of spalled 4H-SiC. Panel a shows that spalled 4H-SiC is bonded to a silicon carrier chip using an epoxy-based die attach film. The gold from the seed layer was not etched away so that the spalled film is highly visible. Scale bar, 5 mm. Panel b shows that HPSI spalled 4H-SiC film is mounted over a stripline on a printed computer board using double sided polyimide tape for the application of microwave pulses during qubit manipulation. Scale bar, 5 mm. Panel c shows that selection of previously spalled substrates is mounted to a granite puck (top right) and then undergoes lapping and polishing to return the surfaces to their original pre-spalling polish. Substrates are then re-spalled with no complications. Note that these substrates were spalled before the crack initiation methods were improved, which explains the irregularly shaped spall regions pictured. Scale bars, 15 mm.

In some implementations, once the metals for spalling are etched away, the freestanding spalled 4H-SiC (typically 10-50 μm thick) is still rigid enough to be handled easily (see FIG. 10) for transfer and bonding to a handle substrate. For example, the spalled films may be routinely bond to a silicon wafer using a 25 μm thick epoxy-based die attached film from AI Technology Inc., as pictured in FIG. 12. The Ni is simply wet etched away from the spalled film and the film then pressed onto the bonding tape and heated to 120° C. to cure the epoxy bond. In other implementations, bonding schemes ensure ohmic contact between the spalled film and the handle substrate by depositing intermediate metal-containing layers which are subsequently annealed before bonding to a highly conducting substrate, such as a Ti-containing ohmic contact layer which is subsequently bonded to a copper handle substrate.

In some implementations, various methods described in the disclosure may apply to ultrahard substrates which have devices on top consisting of patterned metals/dielectrics with a certain thickness (e.g., <10 microns in total thickness). In some implementations, a 4H silicon carbide substrate with metal/dielectric layers varying from 0-8 microns in total thickness may be fully spalled.

In some implementations, making an edge for crack initiation by mechanical cut or wet-etching may be advantageous than defining a cut using a laser. Mechanical cut and/or wet-etching, unlike using a layer, does not cause any melt or damages to the substrate/seed layer in any way directly adjacent to the cut, which is an important advantage because, defining cut with a laser may result in a high temperature (e.g. above 200° C.) and/or lead to a degradation of the seed layer.

### Measurement of Qubit Properties in Spalled Films

In some implementations, spalled 4H-SiC is an attractive approach for heterogeneously integrating 4H-SiC spin-qubit based quantum coherent devices with silicon. Optically active defect spin qubits in 4H-SiC, including transition metal ions such as vanadium, and vacancy complexes such as the nitrogen-vacancy center (NV) and the divacancy (VV) may be widely used for quantum computing, networking, and sensing. The spalling process seeks to overcome scalability challenges of these technologies by creating transferable thin films from semiconductor qubit hosts. It is characterized that the coherence properties of spin qubits subjected to spalling to infer the quality of native spalled films for quantum applications.

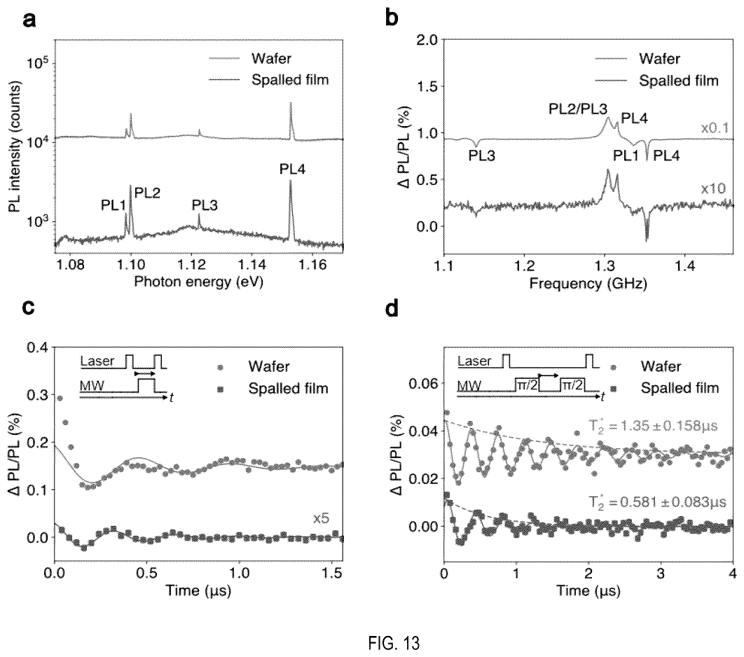

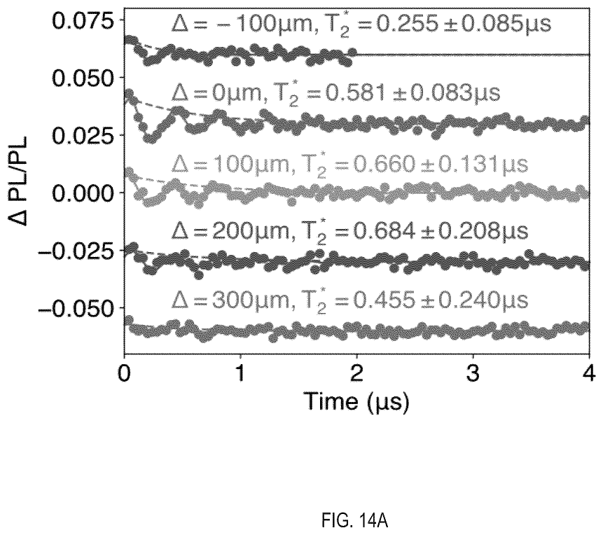

In some implementations, to benchmark the performance of spalled 4H-SiC for quantum applications, the optical and spin properties of neutral-divacancy defects (VV⁰) in spalled high purity semi-insulating (HPSI) 4H-SiC is studied. Photoluminescence spectra of the bulk wafer and the thin film are shown in FIG. 13 panel a. Sharp lines from 1.09-1.16 eV are present in both samples corresponding to the zero phonon lines of PL1-PL4 divacancies. No additional optical broadening is observed in the film as zero-phonon lines on both samples are narrower than the spectrometer resolution limit. FIG. 13 panel b also shows a continuous-wave optically detected magnetic resonance (ODMR) spectra in the absence of an applied external field. Both samples show a pronounced resonance of PL4 divacancies at 1.353 GHz.

FIG. 13 shows comparison of 4H-SiC VV⁰ qubit properties between bulk wafer and spalled film. Panel a shows photoluminescence spectra of 4H-SiC HPSI bulk wafer and spalled film showing the PL1-PL4 divacancy defect lines. Panel b shows continuous-wave (CW) ODMR spectra for the HPSI bulk wafer and spalled film measured as a function of microwave frequency and detected as a normalized change in photoluminescence intensity. Panel c shows Rabi oscillations of the basal (PL4) divacancy in HPSI bulk wafer and spalled film. The driving frequency is resonant to the PL4 dip at 1.353 GHz in the CW ODMR or pulsed ODMR spectra. Panel d shows Ramsey decay of PL4 divacancy defects at a detuning of 3 MHz, showing a bulk T₂*=1.35 μs and a film T₂*=581 ns. The dashed lines illustrate the Ramsey decay envelope. Solid lines are fits, and error bars on the film data are standard errors corresponding to 95% confidence intervals.

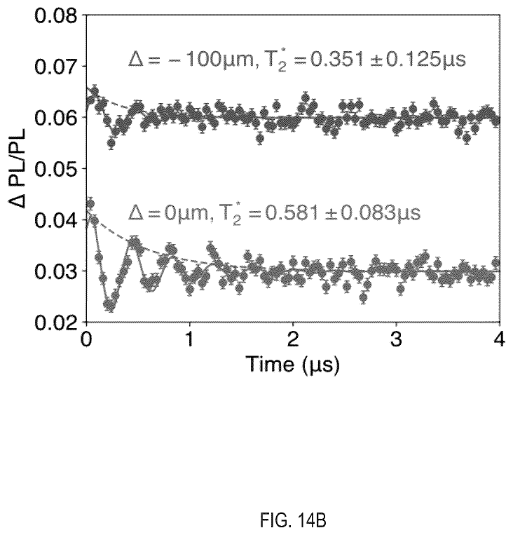

In some implementations, coherent spin control and free-induction decay of the PL4 ensemble centered at 1.353 GHz is shown in panels c and d in FIG. 13. In FIG. 13 panel c, Rabi oscillations are observed by sweeping the duration of a single microwave pulse. Additionally, a Ramsey pulse sequence with a detuning of 3 MHz was used in to characterize the spin T₂* as shown in FIG. 13 panel d. A T₂*=1.35±0.158 us was measured in the bulk wafer, consistent with the literature values for VV⁰ ensembles at this temperature, and a T₂*=0.581±0.083 μs was measured in the film. The lower film T₂* is attributed to additional dephasing caused by inhomogeneous broadening of the ensemble spin resonance, as shown in FIG. 13 panel b. It is speculated that this broadening may be caused by unresolved strain created in the film during the spalling process. Furthermore, roughness of the spalled surface could lead to strained mounting of the film during the measurement. A slight spatial variation of T₂* is observed and explored further in FIGS. 14A and 14B. These observations indicate that a future detailed study which correlates T₂* to microstructural strain in spalled 4H-SiC could provide guidance on how to optimize the quality of spalled films.

FIG. 14A shows Ramsey spatial comparison. The Ramsey experiment in FIG. 13 panel d may be repeated at different positions on the spalled film, along the microwave stripline. With the exception of a single point at Δ=−100 μm, the measured T₂* at each position overlap within the fit error. The data at Δ=0 μm is shown in FIG. 13 panel d. The same microwave π/2-pulse duration, excitation frequency, and power are used at each position. However, strain and film thickness variation may cause variations in the spin resonance and Rabi frequency at each position. The T₂* measured after re-optimization of the resonance frequency at Δ=−100 μm is shown in FIG. 14B.

FIG. 14B shows Ramsey spatial comparison after optimization of pulse parameters. The Ramsey experiment in FIG. 13 panel d may be repeated at Δ=−100 μm following re-optimization of the resonance frequency and π/2-pulse duration. A pulsed ODMR measurement at Δ=−100 μm shows that the PL4 resonance frequency is 1.353 GHz, same as used for all positions measured in FIG. 14A. The Rabi experiment at Δ=−100 μm is shown in FIG. 13 panel c. The π/2-pulse duration at Δ=−100 μm is 82 ns whereas the π/2-pulse duration at Δ=0 μm is 120 ns. The T₂* measured after re-optimization increased by 100 ns yet is still smaller than the value at other positions. This suggests that the spatial variation of the T₂* is not due to Ramsey experimental errors, but possibly due to inhomogeneity in the spalled film.

### CONCLUSION

In various embodiments in the present disclosure, controlled spalling of 4H-SiC has been successfully demonstrated on a wide variety of substrate types and sizes. High yield spalling of this high fracture toughness material is made possible by innovations in the Ni electroplating setup, Ni thickness distribution, crack initiation into the 4H-SiC, and controlled crack propagation in the plating bath. Thickness nonuniformity across an entire spalled film is currently ~5 μm peak-to-peak, limited primarily by further advancements needed in regulation of the peeling process. Intrinsic roughness of 4-degree miscut substrates can be kept under 1 μm peak-to-peak by spalling perpendicular to the miscut direction. Heterogenous integration and substrate re-use show promise, with more complicated schemes to be pursued in future work. An initial demonstration of coherent spin control of a VV⁰ ensemble in 4H-SiC yields a spin T₂* which is ~43% of the bulk value, motivating further study on the microstructure of spalled films. Other goals for future work include spalling full 6- or 8-inch wafers of 4H-SiC as well as exploring the spalling of 4H-SiC substrates with prefabricated devices on the wafer surface.

### Methods: 4H-SiC Substrate Preparation

In some implementations, the 4H-SiC substrates used various embodiments may be grown via physical vapor transport by ST Microelectronics N.V., GlobiTech, Inc., and Wolfspeed, Inc. Wafers spanned from 350 to 500 μm thick and were comprised of n-type (0001) with 4-degree off-axis miscut towards [112̅0], n-type (0001) on-axis, and high purity semi-insulating (HPSI) (0001) and (1010) on-axis substrates. The silicon face of the 4H-SiC substrates was exclusively used for spalling in this work. Immediately following a cycle of SC-1, SC-2, and 10:1 buffered oxide etchant (BOE) cleaning steps, a seed layer of ≤10 nm of Cr or Ti and then 50-100 nm of Au was deposited on the silicon face in an AJA Orion UHV Sputtering System with 2-inch targets. The Cr or Ti was deposited at 100 W RF in 5 mTorr Ar, while the Au was deposited at 100 W DC in 5 m Torr Ar. All wafers were then diced into square dies, and the trench for crack initiation was also cut at this time. These processes utilized a model 7122 Advanced Dicing Technology (ADT) dicing saw with a 6-8 mil thick resin blade containing 46 μm diamond grit.

### Ni Electroplating Conditions

In some implementations, in a general procedure for Ni stressor layer electroplating for spalling, Ni electroplating baths used in this work contained 300 g/L NiCl₂·6H₂O, 30 g/L H₃BO₃, and 10-20 g/L NH₄Cl with current densities ranging from 8-30 mA/cm². All depositions took place at room temperature. The stress of the electroplated Ni was modulated via the NH₄Cl concentration and current density used. Higher NH₄Cl concentrations and higher current densities resulted in higher stress deposits. Ni stress was measured using the bent strip method as defined under ASTM Standard B975 with products (e.g., from Specialty Testing and Development Company). Electroplating baths ranged in size from 120 mL to 2 L, depending on the size of sample to be spalled and the quantity of fluid needed to keep the bath temperature from rising by more than 2° C. at high current densities. The 120 mL baths were used for the 5×5 mm square substrates and simply contained a ⅞ in. spin bar at 150 rpm to agitate the bath. The 2 L baths were used for the 29 mm×29 mm square substrates and employed a Watson-Marlow model 323E peristaltic pump to circulate the solution at ~1 L/m. Spalling handle layers included polyimide tape with silicone adhesive or Revalpha Heat Release Tape by Nitto Denko Corporation.

### 4H-SiC Spalling

In various embodiments, once the Ni thickness and stress have surpassed the GC limit for favorable spalling, the substrate may be spalled using two different approaches. The first approach is to stop the Ni electroplating before a spalling crack self-initiates in the plating bath, generally at ~90% of the experimentally determined Ni thickness at which this occurs. An adhesive handle layer is applied to the top of the Ni and then manually pulled up to initiate and propagate the spalling crack. The second approach is to let the electroplating proceed without interruption, so the spalling crack self-initiates and propagates in the plating bath. Although both approaches were used in this work, it was unexpectedly found that the second approach of allowing the crack to propagate during electroplating almost always yields high-quality intact films, while spalling with the handle layer after electroplating more often results in inhomogeneous and partially spalled films. Making full use of the techniques presented in FIGS. 8 and 9A, Ni thickness and crack initiation for intentional spalling in the plating bath may be jointly optimized such that a crack can open from a single specified edge of the substrate and then slowly propagate across the full substrate. At present, single-crack-front spalls may be produced which yield smooth crack-free 4H-SiC spalled films, as shown in FIG. 10.

### Ni Electroplating COMSOL Simulations

In some implementations, a replica of the experimental electroplating geometry was created in COMSOL, and the Secondary Current Distribution physics interface of the Electrochemistry Module was used to simulate the Ni electroplating dynamics. At all electrode surfaces, the Ni reaction was defined with an equilibrium potential of −0.26 V and a Butler-Volmer kinetics expression was defined for the Ni reaction. The exchange current density for Ni was set to 0.1 A/m², while the anodic and cathodic transfer coefficients were both set to 0.5. At the 4H-SiC+thief cathodes, an additional hydrogen evolution reaction was defined to have 0 V equilibrium potential and a cathodic Tafel kinetics expression. The exchange current density for H was set to 2×10⁻⁵ A/m², while the cathodic Tafel slope was set to −118 mV. Electrolyte conductivity was set to 10 S/m. The study steps involved a current distribution initialization and then a time dependent step in which Ni was deposited for a set amount of time. Because neither a deforming geometry nor a tertiary current distribution was used, the deposition rate is constant and thus the chosen plating time is arbitrary.

### Optical Profiling and Imaging

In some implementations, for post processing and characterization, all Ni thickness and spall depth area scans and line profiles (FIGS. 8, 9A, and 11) were measured with a microscope (e.g., the 20× lens of a Keyence VK-X1000 Laser Scanning Confocal Microscope). Automated image stitching was used for large area scans. Optical microscope images were taken with a differential interference contrast (DIC) enabled Olympus BX60 reflected light microscope and Tucsen MIchrome 5 Pro digital camera.

### Lapping and Chemical Mechanical Polishing of 4H-SiC

In some implementations, spalled 4H-SiC substrates were mounted to a granite puck with the silicon face up using Crystalbond™ 509 wax. The puck was then flipped to face downwards on a polishing pad wetted with slurry. Initial lapping utilized a 3 μm diamond grit slurry to remove the spalling divot and re-planarize the substrates. Next, a 0.5 μm diamond grit slurry removed the surface damage from the 3 μm grit, removing an additional 10 μm of material. Finally, a colloidal silica slurry was used in the chemical mechanical polishing process to ultimately achieve an epi-ready surface, removing <2 μm of material.

### VV⁰ Qubit Measurements

In some implementations, the VV⁰ are excited with below bandgap light from a 905 nm (1.37 eV) diode laser in a cryostat. The bulk sample is measured at 7.9 K and the spalled film is measured at 6.4 K. The spectra in FIG. 13 panel a are recorded using a spectrometer with an InGaAs detector. The spectrometer grating is 600 g/mm and the slit width is 25 μm. For ODMR measurements, optical emission is from a fiber-coupled a photodiode (e.g., Femto OE200-IN1), detected using a lock-in amplifier (Signal Recovery 7265), with the reference oscillator corresponding to square wave amplitude modulation of the microwave drive at 503 Hz and 50% duty cycle. In FIG. 13 panels c and d, an optical pulse is used to initialize the spin state, microwave pulses coherently manipulate the spins, and a second optical pulse causes a readout of spin-state dependent luminescence. In both cases the driving field on the sample is aligned to the c-axis.

In some other embodiments, a computer-readable medium comprising instructions which, when executed by a computer, cause the computer to carry out the above methods. The computer-readable medium may be referred as non-transitory computer-readable media (CRM) that stores data for extended periods such as a flash drive or compact disk (CD), or for short periods in the presence of power such as a memory device or random access memory (RAM). In some embodiments, computer-readable instructions may be included in a software, which is embodied in one or more tangible, non-transitory, computer-readable media. Such non-transitory computer-readable media can be media associated with user-accessible mass storage as well as certain short-duration storage that are of non-transitory nature, such as internal mass storage or ROM. The software implementing various embodiments of the present disclosure can be stored in such devices and executed by a processor (or processing circuitry). A computer-readable medium can include one or more memory devices or chips, according to particular needs. The software can cause the processor (including CPU, GPU, FPGA, and the like) to execute particular processes or particular parts of particular processes described herein, including defining data structures stored in RAM and modifying such data structures according to the processes defined by the software. In various embodiments in the present disclosure, the term “processor” may mean one processor that performs the defined functions, steps, or operations or a plurality of processors that collectively perform defined functions, steps, or operations, such that the execution of the individual defined functions may be divided amongst such plurality of processors.

Reference throughout this specification to features, advantages, or similar language does not imply that all of the features and advantages that may be realized with the present solution should be or are included in any single implementation thereof. Rather, language referring to the features and advantages is understood to mean that a specific feature, advantage, or characteristic described in connection with an embodiment is included in at least one embodiment of the present solution. Thus, discussions of the features and advantages, and similar language, throughout the specification may, but do not necessarily, refer to the same embodiment.

Furthermore, the described features, advantages and characteristics of the present solution may be combined in any suitable manner in one or more embodiments, for non-limiting examples, a portion from one or more embodiment may be combined with another portion of other embodiments. One of ordinary skill in the relevant art will recognize, in light of the description herein, that the present solution can be practiced without one or more of the specific features or advantages of a particular embodiment. In other instances, additional features and advantages may be recognized in certain embodiments that may not be present in all embodiments of the present solution.

1. A method for spalling a substrate, the method comprising:
obtaining a substrate;
depositing a seed layer on the substrate;
generating an edge around the seed layer for crack initiation in the substrate; and
electroplating a stressor layer on the seed layer in an electroplating bath to spall the substrate to obtain a spalled substrate and a spalled film.

2. The method of claim 1, wherein a thickness of the substrate spans from 250 to 750 μm, inclusive.

3. The method of claim 1, wherein the substrate comprises a single crystal substrate including at least one of the following: 4H, 6H, and 3C silicon carbide, sapphire, aluminum nitride, and/or diamond.

4. The method of claim 1, wherein:
before depositing the seed layer on the substrate, a patterned device layer is disposed on the substrate;
the depositing the seed layer on the substrate comprises depositing the seed layer on the patterned device layer;
the patterned device layer comprises patterned metals and patterned dielectrics; and
the patterned device layer is equal to or thinner than 10 μm.

5. The method of claim 1, wherein:
the seed layer is electrically conductive, and comprises at least one of the following elements: Cr, Ti, Au, Ta, W, Ni, or Pt.

6. The method of claim 1, wherein, the generating the edge comprises:
disposing a trench at an edge of the seed layer deep into the substrate to generate the edge around the seed layer for crack initiation, wherein the trench is created with a dicing blade cut and the trench is equal to or deeper than 5 μm.

7. The method of claim 1, wherein, the generating the edge comprises:
wet-etching the seed layer to generate the edge around the seed layer for crack initiation.

8. The method of claim 7, wherein, the wet-etching the seed layer comprises:
conformally depositing the seed layer on the substrate;
masking the seed layer by disposing a flat carrier material with adhesive to bond a top surface of the seed layer; and
using wet etchant to remove the seed layer from sides and around the edge of the substrate.

9. The method of claim 1, wherein:
the stressor layer comprises Ni; or
the electroplating bath comprises at least one of the following: NiCl₂·6H₂O, CoCl₂·6H₂O, FeCl₂·4H₂O, FeCl₃·6H₂O, 30 g/L H₃BO₃, and NH₄Cl.

10. The method of claim 1, wherein, the electroplating the stressor layer on the seed layer in the electroplating bath comprises:
electroplating the stressor layer on the seed layer in the electroplating bath with a current density with a range from 8 to 50 mA/cm², inclusive.

11. The method of claim 1, wherein, when electroplating the stressor layer on the seed layer in the electroplating bath, the method further comprises:
disposing an auxiliary cathode between the seed layer and an anode in the electroplating bath for manipulating a thickness or uniformity of the stressor layer.

12. The method of claim 1, further comprising:
lapping a top surface of the spalled substrate to remove a divot from the spalled substrate;
polishing the top surface of the spalled substrate; and
subsequently spalling the spalled substrate.

13. The method of claim 1, further comprising:
bonding the spalled film onto a second substrate, wherein the second substrate comprises a single crystal substrate or polycrystalline substrate, comprising at least one of the following with undoped or doped with elements: silicon carbide, diamond, silicon, aluminum nitride, and copper.

14. An apparatus comprising a film, wherein:
the film is made by a method for spalling a substrate, the method comprising:
obtaining the substrate;
depositing a seed layer on the substrate;
generating an edge around the seed layer for crack initiation in the substrate; and
electroplating a stressor layer on the seed layer in an electroplating bath to spall the substrate to obtain the film.

15. The apparatus of claim 14, wherein a thickness of the substrate spans from 250 to 750 μm, inclusive.

16. The apparatus of claim 14, wherein the substrate comprises a single crystal substrate including at least one of the following: 4H, 6H, and 3C silicon carbide, sapphire, aluminum nitride, and/or diamond.

17. The apparatus of claim 14, wherein:
before depositing the seed layer on the substrate, a patterned device layer is disposed on the substrate;
the depositing the seed layer on the substrate comprises depositing the seed layer on the patterned device layer;
the patterned device layer comprises patterned metals and patterned dielectrics; and
the patterned device layer is equal to or thinner than 10 μm.

18. The apparatus of claim 14, wherein, the generating the edge comprises:
disposing a trench at an edge of the seed layer deep into the substrate to generate the edge around the seed layer for crack initiation, wherein the trench is created with a dicing blade cut and the trench is equal to or deeper than 5 μm.

19. The apparatus of claim 14, wherein:
when electroplating the stressor layer on the seed layer in the electroplating bath, the method further comprises:
disposing an auxiliary cathode between the seed layer and an anode in the electroplating bath for manipulating a thickness or uniformity of the stressor layer.

20. A device comprising:
a film, wherein the film is made by a method for spalling a substrate, the method comprising:
obtaining the substrate;
depositing a seed layer on the substrate;
generating an edge around the seed layer for crack initiation in the substrate; and
electroplating a stressor layer on the seed layer in an electroplating bath to spall the substrate to obtain the film; and
a second substrate, wherein the film is bonded onto the second substrate.
